(19) United States
(12) Patent Application Publication
(10) Pub. No.: US 2017/0323761 A1
(43) Pub. Date: Nov. 9, 2017

(54) CHARGED PARTICLE DETECTOR

(71) Applicant: RAINTREE SCIENTIFIC INSTRUMENTS (SHANGHAI) CORPORATION, Shanghai (CN)

(72) Inventors: Hu Luo, Shanghai (CN); Xu Zhang, Shanghai (CN)

(21) Appl. No.: 15/585,354

(22) Filed: May 3, 2017

(30) Foreign Application Priority Data
May 3, 2016 (CN) 201610285009.0

(51) Int. Cl. H01J 37/244; H01J 37/18; H01J 37/28; H01J 37/285

(52) U.S. Cl. CPC H01J 37/244; H01J 37/285; H01J 37/18; H01J 37/28

(57) ABSTRACT

A charged particle detector with high detection efficiency is presented in this patent. This charged particle detector contains a grid electrode used for attracting charged particles, a convertor with the shape of particle entrance area smaller than the particle exit area, which is used for converging charged particles and converting ions into electrons in the ion detection mode, an electron detection unit used for detecting secondary electrons and amplifying the signal detected, and a metal shielding. This optimized detector has a simple construction, is easy to assemble and has a low manufacturing cost.

### CROSS REFERENCE TO RELATED APPLICATIONS

This present disclosure claims priority to Chinese patent application No. 201610285009.0 filed on May 3, 2016, the contents of which will be incorporated herein by reference in its entirety.

### TECHNICAL FIELD OF THE INVENTION

The present invention relates to the field of charged particle imaging, analysis and processing equipments, especially relates to charged particle detection devices and charged particle instruments containing charged particle detectors.

### BACKGROUND OF THE INVENTION

Charged particle imaging and analysis processing equipments are widely used in the semiconductor and material industry, which utilize charged particles (ion or electron) of high energy to observe or fabricate objects directly, such as, scanning electron microscope (SEM), focused ion beam (FIB) and dual beam system containing both SEM and FIB.

The typical structure diagram of a FIB or SEM is shown in FIG. 1 and the working principle is as follows. A particle beam is emitted from the particle source 101 and then focused into a fine beam with diameter of sub-micrometer through the electromagnetic lens 102. The fine beam 104 can perform regulated scanning on the sample surface 105 with the help of deflection and scanning coils 103. The high energy particles of the fine beam 104, as called primary beam, irradiate sample and stimulate secondary particles 107. The secondary particles 107 will be secondary electrons, backscatter electrons, Auger electron and X-ray if the primary beam is an electron beam. If the primary beam is an ion beam, then the secondary particles 107 will be secondary electrons, secondary ions and neutral atoms. All the secondary particles 107 can be detected by the corresponding particle detector 106. Nowadays, secondary electron and secondary ion can be detected with Everhart-Thornley detector or Micro-channel plate (MCP), among others. The secondary particle will be converted into electrical signal after striking detectors mentioned above. The electrical signal is then amplified further and processed into gray scale values and displayed as image.

A common Everhart-Thornley detector 106 is shown in FIG. 2, which includes a grid electrode 201, scintillator 202, light transmission guide 203 and photomultiplier tube (PMT) 204. In the case of secondary electron detection, secondary electrons 205 emitted from sample 207 are attracted by the grid electrode 201 and then accelerated onto the scintillator 202 for converting into photons. The photons are transmitted through a light transmission guide 203 made with glass or organic glass to PMT 204. Finally, PMT 204 converts the incoming photons into electrons again and output an amplified electrical current for imaging. This type of detector can also be used to detect ions by keeping the grid and scintillator at a negative or positive potential to collect positive or negative ions and convert their energy into photons. However, the existing scintillators have very low ion-to-photon conversion efficiency thus very low ion detection efficiency. In addition, even with the same energy as electrons, ions can cause larger damage to the scintillator in the detection process compared to the electrons because of their much heavier mass. Thus it is rare to use scintillator type detector to detection ions.

The secondary ion imaging has an advantage of better contrast compared with secondary electron imaging, which is very useful for sample surface analysis, particularly in elemental analysis. Therefore, it is necessary to improve ion detection efficiency of the scintillator type of detector.

### SUMMARY OF THE INVENTION

An object of this invention is to provide a charged particle detector that can detect ions or electrons emitted from sample by bombarding of a primary beam, such as a focused electron beam and a focused ion beam.

One feature of this invention provides an apparatus to detect either ions or electrons. This charged particle detector comprises:
a grid electrode used for attracting charged particles;
a convertor with the shape of particle entrance area smaller than the area of particle exit, which is used for converging charged particles and converting ions into electrons in the ion detection mode;
an electron detection unit used for detecting secondary electrons and amplifying the signal detected;
and a metal shielding.

The other feature of this invention provides a charged particle instrument, which includes the charged particle detector comprising:
a grid electrode used for attracting charged particles;
a convertor with the shape of particle entrance area smaller than the area of particle exit, which is used for converging charged particles and converting ions into electrons in the ion detection mode;
an electron detection unit used for detecting secondary electrons and amplifying the signal detected;
and a metal shielding.

Compared with existing charged particle detector technology, charged particle detector according to the present invention has higher detection efficiency of secondary particles generated at sample, such as secondary electrons and secondary ions. In addition, optimized mechanical design simplifies the whole detector construction, which can greatly reduce the manufacturing cost.

### BRIEF DESCRIPTION OF THE DRAWINGS

For a comprehensive understanding of this invention and its advantages, the following description is made with reference to the accompanying drawings, in which:

FIG. 1 shows the typical diagram of a focused ion beam or electron beam system of existing technology.

FIG. 2 shows the typical diagram of an Everhart-Thornley detector.

FIG. 3 is a first preferred embodiment of a charged particle detector according to this invention.

FIG. 4 is a second preferred embodiment of a charged particle detector according to this invention.

FIG. 5 is a third preferred embodiment of a charged particle detector according to this invention.

FIG. 6a shows the secondary ion path from the sample to the ion-to-electron convertor according to the preferred embodiment of FIG. 4 in the ion detection mode.

FIG. 6b shows the secondary electron path from the ion-to-electron convertor onto the scintillator plate according to the preferred embodiment of FIG. 4 in the ion detection mode.

FIG. 7 shows the electrical field distribution of the preferred embodiment as described in FIG. 4 in the ion detection mode.

FIG. 8 shows the secondary electron path of the preferred embodiment as described in FIG. 4 in the electron detection mode.

FIG. 9 shows the electrical field distribution of the preferred embodiment as described in FIG. 4 in the electron detection mode.

FIG. 10 shows a preferred embodiment of a charged particle instrument, including a charged particle detector, according to the present invention.

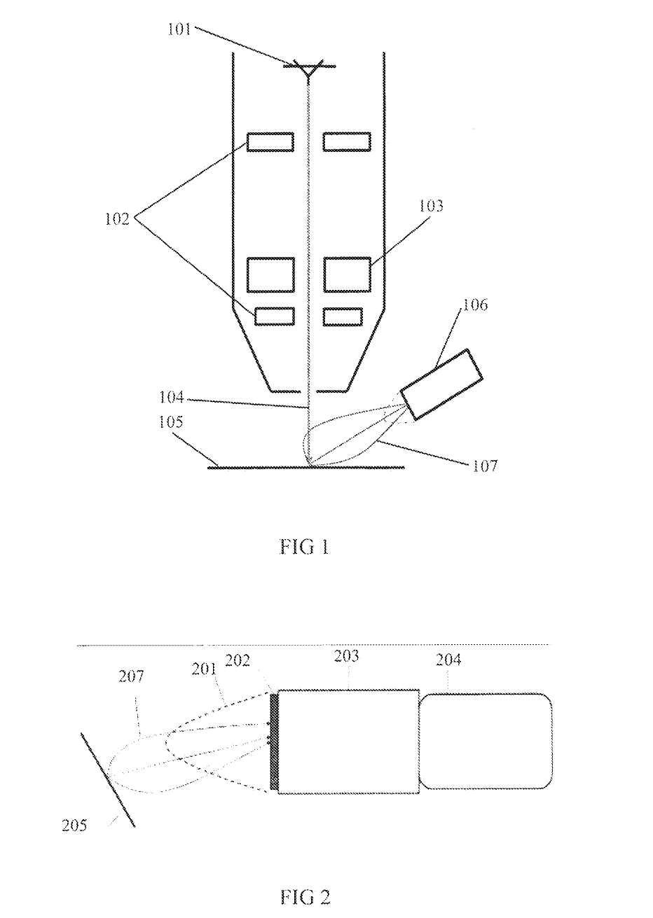

### DETAILED DESCRIPTION OF THE PREFERRED EMBODIMENTS

This invention provides a charged particle detector which can detect either electrons or ions by utilizing an ion-to-electron convertor between a grid electrode and an electron detection unit. The detector includes a grid electrode used to attract charged particle, an ion-to-electron convertor with a shape of particle entrance area smaller than the particle exit area, an electron detection unit and a metal shielding. In operation, the whole detector is preferably installed with an angle relative to the primary beam of a charged particle instrument, such as SEM, FIB and dual beam system containing both SEM and FIB. The grid electrode, ion-to-electron convertor and electron detection unit, preferably, are mounted coaxially, which can help to realize higher detection efficiency and also simplify the detector structure at the same time.

In order to get higher ion detection efficiency, the material of the ion-to-electron convertor as described shall have good secondary electron emission yield, preferably, the material can include, but not limited to aluminum, aluminum oxide and beryllium copper.

The as described ion-to-electron convertor can be of any shape with entrance area smaller than the exit area, such as, frustum, frustum of a cone, frustum of a sphere or polyhedron, combination of frustum of a cone and cylinder etc. This optimized shape helps to focus emitted secondary electrons into a spot onto the scintillator, which can largely reduces the chance of secondary electrons emitted from the convertor escaping from the scintillator without producing photons, therefore, result in an improved ions detection efficiency. The cone angle is preferably between 20° to 90° when using the shape of frustum of a cone or combination of frustum of a cone with cylinder as the described ion-to-electron convertor.

The as described charged particle detector can detect both positive and negative charged particles by switching the polarity of the voltages on the grid electrode and the convertor during operation.

For example, in the positive ion detection mode, the grid electrode is set between −400 V and −50 V, the ion-to-electron convertor is set between −3 kV and −2 kV. But in the electron detection mode, the grid electrode is set between +50 V and +200 V, and the ion-to-electron to convertor is set between 0 and +500 V.

It needs to be pointed out that all potential values as described in this invention are relative values as referenced to the potential of the test sample.

The electron detection unit in the as described charged particle detector is used to detect electrons which emitted from the sample or the inner surface of the ion-to-electron convertor in accordance with the electron or ion detection mode. One preferred selection of the electron detection unit is scintillator type of detector, which includes scintillator, light transmission guide of glass and PMT. The scintillator shall be placed inside of the metal shielding, and light transmission guide and PMT can be placed inside or outside of the metal shielding. The other preferred selection of the electron detection unit is semiconductor photodiode or MCP.

During the detection process, the charged particle trajectories are as follows. In the ion detection mode, positive secondary ions are attracted first by the gird electrode fed with negative potential relative to the sample, then pass into the ion-to-electron convertor and hit the inner surface of the convertor for producing secondary electrons. The secondary electrons are then focused onto the scintillator front surface with about 10 kV voltage. Within the scintillator, the high energy secondary electrons are collected to stimulate photons, which pass through the light transmission guide into the PMT. In the PMT, the photons are converted into an electrical current and amplified by PMT. This amplified electrical current is outputted finally for imaging. In the electron detection mode, secondary electrons, which are produced by impact of primary electron beam or ion beam on the sample, pass through the ion-to-electron convertor without collision and are focused directly onto the scintillator surface for further processing just like the ion detection process. The ions and electrons detection efficiency of the detector as shown in this invention can be over 90%, and the electron detection efficiency can even reach 99%. In addition, the optimized design of the convertor structure makes the construction simple thereby reduces the cost of manufacturing.

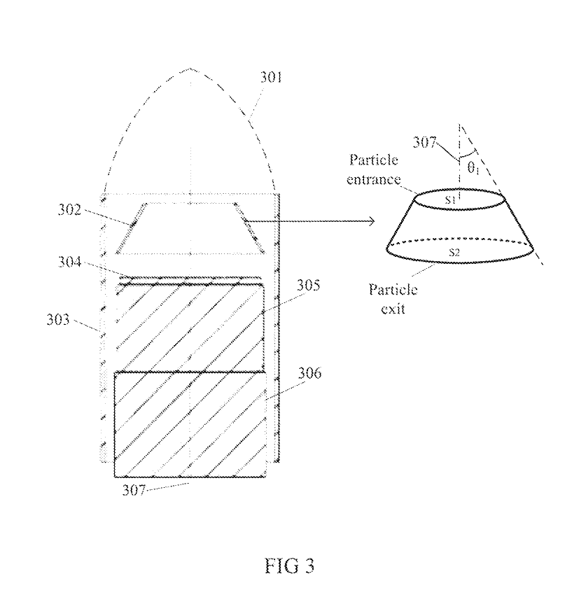

FIG. 3 shows a preferred embodiment of the charged particle detector according to the present invention. In the embodiment shown in FIG. 3, a cross section view of the charged particle detector is shown along the central axis 307. The detector consists of a grid electrode 301, an ion-to-electron convertor 302, a metal shielding 303, and an electron detection unit which includes a scintillator 304, a light transmission guide 305, a photomultiplier tube 306. All these components are mounted coaxially along central axis 307. The convertor 302 is a frustum of a cone with the small end facing upstream of incoming beam and large end facing scintillator. The areas of the small and large ends are S1 and S2, respectively, with S1<S2. The half angle θ₁ of the convertor frustum is preferably 20° as shown in FIG. 3.

In the positive ion detection mode, a negative electrical potential in the range of −400 V to −50 V is applied to the gird electrode 301 to attracted the positive ions produced at sample by primary ion beam. The potential of the ion-to-electron convertor 302 is set in the range of −3 kV to −2 kV. This negative potential is to attract the positive ions and accelerate them to high energy as they impact the inner surface of the convertor to realize the conversion of ions into electrons. An electrical potential in the range of +7 kV to +12 kV is maintained on the scintillator 304 to collect secondary electrons which are emitted as positive ions bombarding the convertor. The secondary electrons impacting the scintillator 304 are converted into photons. These photons pass through the light transmission guide 305 to the PMT 306.

To switch to the electron detection mode, one just need to switch the polarity of the electrical potential of the grid electrode 301 and convertor 302 as described above in the ion detection mode, by setting a voltage of +50 to +200 V to the grid electrode 301 and 0 to +500 V to the convertor 302. Under the force of the electrical field, low energy secondary electrons generated at sample will pass through the grid electrode 301 and the convertor 302 and strike the scintillator 304 to produce photons. Because of the special shape of the convertor, almost all the electrons can pass through the convertor 302 without striking its surface, ensuring high detection efficiency for the electrons.

As mentioned above, it is rare to use scintillator to directly detect ion in practice due to the low ion-to-photon conversion ratio and large damage to scintillator. But in this invention, an ion-to-electron convertor is applied to convert secondary ions into electrons in the ion detection mode to avoid ions bombarding onto the scintillator directly, which can greatly improve the ion detection efficiency and prolong the service life of the scintillator at the same time.

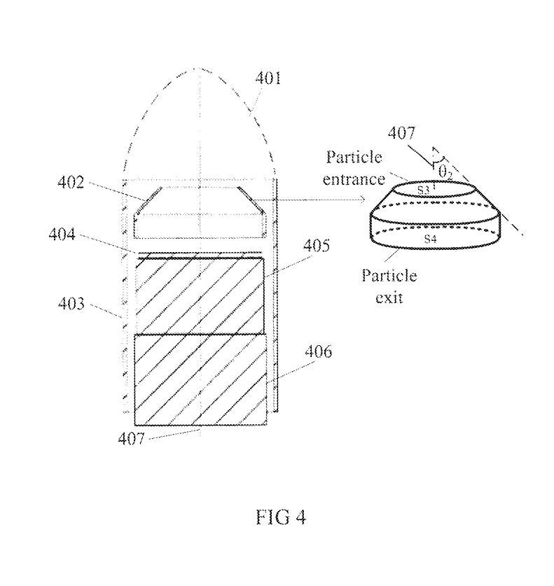

FIG. 4 shows another preferred embodiment of the charged particle detector according to the present invention. In this embodiment, the shape of the ion-to-electron convertor 402 is a combination of frustum of a cone with cylinder. The frustum end faces the grid electrode 401 and cylinder end faces the scintillator 404. Area of the particle entrance port of the convertor S3, area of the particle exit port S4 and half cone angle of frustum θ₂ are also shown in FIG. 4, with S3<S4. The cylinder portion of the convertor helps to keep the conversion electrode structure more stable, thereby realizing high detection efficiency. The convertor 402, scintillator 404, light transmission guide 405 and PMT 406 are placed inside the metal shielding 403, and all the components are mounted coaxially along the central axis 407.

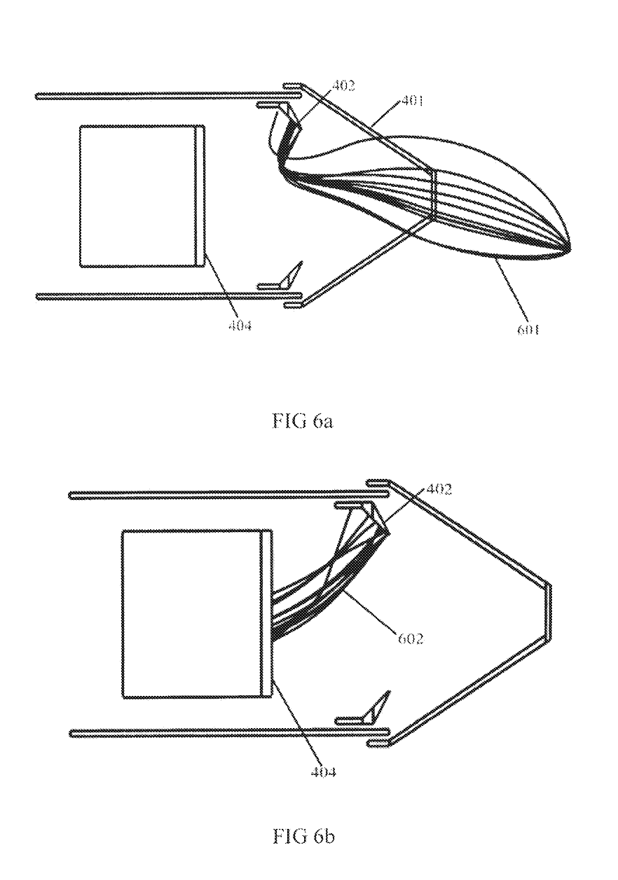

In the ion detection mode, taking Si⁺ as the secondary ion for example, the voltage of the grid electrode 401 is set at range between −400 V and −50 V, voltage of the ion-to-electron convertor 402 is set between −3 kV and −2 kV and voltage of the scintillator 404 is set between +7 kV and +12 kV. Under the force of the electrical field, low energy Si⁺ ions generated at sample pass through the grid electrode and hit the inner surface of the convertor 402. Simulated trajectories 601 of Si⁺ ions are shown in FIG. 6a. The simulated collection efficiency of Si⁺ ions collected by the convertor 402 is 96%. From FIG. 6a, it can be seen that most of the Si⁺ ions are collected on the inside surface of the convertor cone 402. As Si⁺ ions strike inner surface of the convertor 402, they produce secondary electrons which are then attracted onto the scintillator 404. The simulated trajectories 602 of the emitted secondary electrons are shown in FIG. 6b. It can be seen that secondary electrons emitted from different locations of convertor 402 are focused onto the center of the scintillator 404, even including the electrons on the front end of the convertor 402. The electron detection efficiency simulated here is 94%. Because of the special shape of the convertor 402, a converging electrical field is found between the convertor 402 and the scintillator 404, which can focus the secondary electrons emitted from the convertor 402 into a small spot on the scintillator 404, thereby improve their detection efficiency of the scintillator. If assuming that every Si⁺ ion can generate one secondary electron when striking the convertor, then the combined ion detection efficiency of this embodiment is about 90%. In practice, the detection efficiency will vary with the type of ions, the voltages used and the geometry of the system.

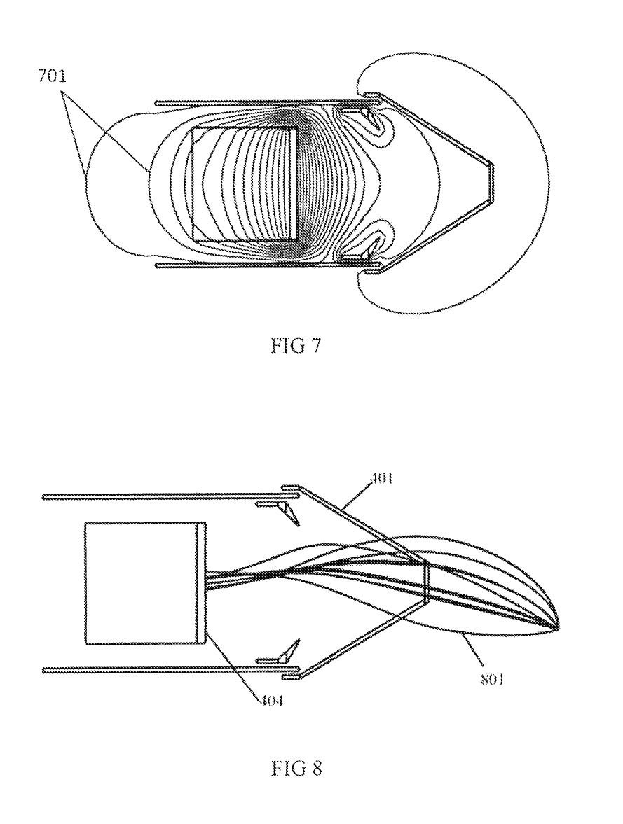

FIG. 7 shows the electrical equipotential line distribution 701 generated by the grid electrode 401, the convertor 402 and the scintillator 404 in the ion detection mode for the embodiment shown in FIG. 4.

In the electron detection mode, the voltage of the grid electrode 401 is set in the range from +50 to +200 V, the voltage of the ion-to-electron convertor 402 is set in the range from 0 to +500 V and the voltage of the scintillator 404 is set in the range from +7 to +12 kV. The simulated trajectories 801 of electrons are shown in the FIG. 8. As shown in FIG. 8, the secondary electrons emitted from sample pass through the grid electrode 401 and the convertor 402 and arrive directly onto the center of the scintillator 404. The electron detection efficiency simulated here is about 99%, therefore almost all secondary electrons generated at sample are detected.

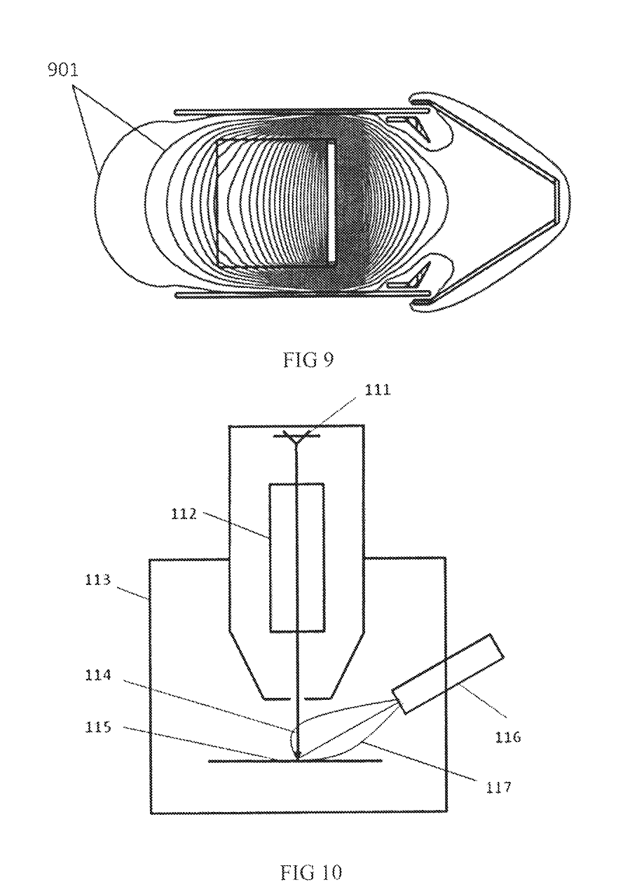

FIG. 9 shows the equipotential line distribution 901 generated by the grid electrode 401, the convertor 402 and the scintillator 404 in the electron detection mode for the embodiment shown in FIG. 4.

Note that all the particle trajectories, 601 in FIG. 6a, 602 in FIG. 6b and 801 in FIG. 8, are simulation results, and some of the trajectories are overlapping therefore hidden in the corresponding figures. Those skilled in the art can comprehend that this overlapping is normal and should be anticipated, because of the high density of particles used in the simulation. The same overlapping phenomenon is also found in equipotential line simulation of FIG. 7 and FIG. 9.

Compared with the embodiment shown in FIG. 3, the ion-to-electron convertor in the embodiment shown in FIG. 4 has an improved structure which has better mechanical stability, thereby further ensures the high detection efficiency of the detector.

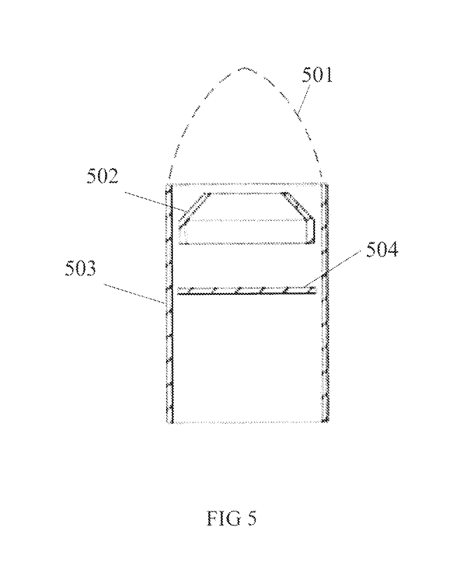

FIG. 5 shows one more embodiment of the charged particle detector according to the present invention. In the embodiment shown in FIG. 5, a center cross section view of the charged particle detector is shown. This charged particle detector comprises of a grid electrode 501, an ion-to-electron convertor 502, an electron detection unit 504 and a metal shielding 503. The electron detection unit 504 described here is of semiconductor photodiode or multichannel photomultiplier (micro-channel plate) type. The grid electrode 501, convertor 502 and electron detection unit 504 are placed in a coaxial fashion. The ion-to-electron convertor 502 has the same construction as 402 as shown in FIG. 4. It needs to be pointed out that the structure of the ion-to-electron convertor 502 is not limited to the given shapes shown. It can be of any shapes with the particle entrance area facing the grid electrode 501 smaller than the particle exit area facing the electron detection unit 504.

For the embodiment shown in FIG. 5, the potential values of the grid electrode 501 and the ion-to-electron convertor 502 can be set to be the same as those described in the embodiment of FIG. 4. And the electron detection unit 504, preferably, is maintained at a voltage ranging from +7 to +12 kV to realize high detection efficiency. The path of ions in the ion detection mode is as follows. Secondary ions emitted at sample pass through the grid electrode 501 and hit onto the inner surface of the convertor 502 to generate secondary electrons. Secondary electrons generated are then attracted onto the electron detection unit. In the electron detection mode, secondary electrons emitted at sample are detected directly by the electron detection unit 504 after passing through the grid electrode 501 and the convertor 502.

When the electron detection unit 504 is of semiconductor photodiode type, secondary electrons with energy in the range from 7 to 12 keV strike the semiconductor photodiode and produce multiple electron-hole pairs within. With a bias on the photodiode the electron-hole pairs separate, forming an amplified current which can then be extracted and further processed for image display.

This invention also provides a charged particle instrument, which contains charged particle detectors according to this invention. FIG. 10 shows a preferred embodiment of the charged particle instrument. During operation, a charged particle beam 114 emitted from a charged particle source 111 passes through an electron optics system 112, which is used for focusing and deflecting the charged particle beam 114, and bombards the sample 115 placed in a vacuum chamber 113, wherein secondary particles are produced. The secondary particles are then detected by a charged particle detector 116 according to the present invention. Preferably, the charged particle detector is installed with an angle relative to the primary beam of the charged particle instrument, wherein the charged particle instrument can include, but not limited to, scanning electron microscope, focused ion beam and dual beam system consisting of scanning electron microscope and focused ion beam.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufactures, composition of matter, means, methods and steps described in the specification. As ordinary people skilled in the art will readily appreciate from the disclosure of the present invention, processes, methods and steps that perform substantially the same function or achieve substantially the same result as the corresponding embodiments described herein will occur to them and may be utilized according to the present invention. Accordingly, the appended claims are intended to include within their scope of such processes, machines, manufactures, compositions of matter, means, methods or steps.

We claim as following:

1. A charged particle detector to detect electrons and ions, comprising:
a grid electrode to attract ions or electrons by applying switchable potential relative to a sample;
an ion-to-electron convertor to convert ion into electron in the ion detection mode with a shape of which the particle entrance opening area is smaller than the particle exit opening area;
an electron detection unit to detect the secondary electrons emitted from sample directly or electrons produced in the ion-to-electron convertor; and
a metal shielding.

2. The ion-to-electron convertor according to claim 1, wherein the shape of the ion-to-electron convertor is frustum of a cone.

3. The ion-to-electron convertor according to claim 2, wherein the half cone angle of the frustum of a cone of the ion-to-electron convertor is between 20° and 90°.

4. The ion-to-electron convertor according to claim 1, wherein the material of the ion-to-electron convertor is aluminum, aluminum oxide and beryllium copper, which have good secondary electron emission yield.

5. The charged particle detector according to claim 1 wherein the grid electrode, the ion-to-electron convertor and the electron detection unit are coaxially mounted.

6. The charged particle detector according to claim 1 wherein the voltage of the grid electrode and the ion-to-electron convertor can be switched from positive to negative potential relative to the sample potential so as to detect electrons or ions.

7. The charged particle detector according to claim 1, wherein the charged particles are secondary ions, wherein the secondary ions pass through the grid electrode first then bombard the inner surface of the ion-to-electron convertor to product secondary electrons, wherein the secondary electrons exit the ion-to-electron convertor and are finally detected by the electron detection unit.

8. The charged particle detector according to claim 1, wherein the charged particles are secondary electrons, wherein the secondary electrons are collected directly by the electron detection unit after passing through the grid electrode and openings of the ion-to-electron convertor.

9. The charged particle detector according to claim 1, wherein the electron detection unit comprising:
a scintillator to attract electrons and then convert the incoming electrons into photons;
a light transmission guide to transmit photons; and
a photomultiplier tube to convert photons into electrons and output amplified electrical current.

10. The charged particle detector according to claim 1, wherein the electron detection unit is semiconductor photodiodes or multichannel photomultiplier (microchannel plate or MCP).

11. The charged particle detector according to claim 1, wherein the charged particle detection efficiency is equal or greater than 90%.

12. The charged particle detector according to claim 1, wherein the charged particle detection efficiency can be equal or better than 99% when detecting secondary electrons.

13. A charged particle instrument, comprising:
a charged particle source to produce a charged particle beam;
an electron optics system to focus and deflect the charged particle beam;
a vacuum chamber to provide a high vacuum working environment; and
a charged particle detector according to claim 1, to detect secondary charged particles from a sample.

14. The charged particle instrument according to claim 13, wherein the charged particle instrument can be scanning electron microscope, focused ion beam, and dual beam system consisting of scanning electron microscope and focused ion beam.
